(19) United States
(12) Patent Application Publication
(10) Pub. No.: US 2022/0357722 A1
(43) Pub. Date: Nov. 10, 2022

(54) SYSTEMS AND METHODS FOR PREVENTING DATA LOSS IN LIQUID COOLED DATA CENTERS DURING FACILITY FLUID FAILURE

(71) Applicant: Dell Products L.P., Round Rock, TX (US)

(72) Inventors: Adam KELLY, Georgetown, TX (US); Travis GASKILL, Austin, TX (US)

(73) Assignee: Dell Products L.P., Round Rock, TX (US)

(21) Appl. No.: 17/316,127

(22) Filed: May 10, 2021

(51) Int. Cl. G05B 19/4155

(52) U.S. Cl. CPC G05B 19/4155; G05B 2219/49216

(57) ABSTRACT

A method may include determining whether a fault has occurred in connection with a distribution unit for a fluidic network. The method may also include operating a plurality of three-way valves in a normal mode of operation in absence of the fault, wherein in the normal mode, the coolant fluid flows in parallel through the heat exchanger and the fluidic network. The method may also include operating the plurality of three-way valves in a failure mode in response to the fault, wherein in the failure mode, the coolant fluid flows in serial through the heat exchanger, then the fluidic network.

### TECHNICAL FIELD

The present disclosure relates in general to information handling systems, and more particularly to preventing data loss in liquid cooled data centers during facility fluid failure.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

To control temperature of components of an information handling system, an air mover may direct air over one or more heatsinks thermally coupled to individual components. Traditional approaches to cooling components may include a “passive” cooling system that serves to reject heat of a component to air driven by one or more system-level air movers (e.g., fans) for cooling multiple components of an information handling system in addition to the peripheral component. Another traditional approach may include an “active” cooling system that uses liquid cooling, in which a heat-exchanging cold plate is thermally coupled to the component, and a chilled fluid is passed through conduits internal to the cold plate to remove heat from the component.

Historically, liquid cooling efforts focused primarily on cooling central processing units, but cooling of memory modules (e.g., dual inline memory modules or DIMMs) may become common in the future. In order to cool DIMMs, a manifold may run directly on either side of each DIMM module, in a channel between DIMMs. Additionally, a thermal interface material may be present between the DIMMs and the liquid cooled manifold. This manifold and thermal interface material may allow for optimal DIMM cooling with liquid, but may prevent air cooling of the DIMMs due to indirect contact between the DIMMs and the airstream. If there is a failure in the method by which heat is removed from the liquid cooling loop, such DIMMs may overheat. As DIMMs store volatile memory, data center power loss may result in data loss if DIMMs are suddenly power cycled. Additionally, if the cooling mechanism for the liquid cooling loop is compromised, using local air movers to cool DIMMs may be insufficient to provide the cooling necessary for safe system shutdown due to increased air flow impedance created by the liquid cooling manifold and thermal interface materials.

### SUMMARY

In accordance with the teachings of the present disclosure, the disadvantages and problems associated with thermal control of an information handling system may be substantially reduced or eliminated.

In accordance with embodiments of the present disclosure, a server enclosure may include a plurality of information handling system servers, a heat exchanger configured to receive a coolant fluid from a distribution unit external to the server enclosure and return the coolant fluid to the distribution unit and further configured to cool air expelled from the server enclosure to an exterior of the server enclosure by transferring heat from the air to the coolant fluid, a fluidic network configured to receive the coolant fluid from the distribution unit and return the coolant fluid to the distribution unit and further configured to cool one or more components of the plurality of information handling system servers by transferring heat from the one or more components to the coolant fluid, a plurality of three-way valves fluidically coupled to the heat exchanger and the fluidic network and configured to convey the fluid in response to control signals received by the plurality of three-way valves, and a controller. The controller may be configured to determine whether a fault has occurred in connection with the distribution unit, operate the plurality of three-way valves in a normal mode of operation in absence of the fault, wherein in the normal mode, the coolant fluid flows in parallel through the heat exchanger and the fluidic network, and operate the plurality of three-way valves in a failure mode in response to the fault, wherein in the failure mode, the coolant fluid flows in serial through the heat exchanger, then the fluidic network.

In accordance with these and other embodiments of the present disclosure, a method may be used in a server enclosure having a plurality of information handling system servers, a heat exchanger configured to receive a coolant fluid from a distribution unit external to the server enclosure and return the coolant fluid to the distribution unit and further configured to cool air expelled from the server enclosure to an exterior of the server enclosure by transferring heat from the air to the coolant fluid, a fluidic network configured to receive the coolant fluid from the distribution unit and return the coolant fluid to the distribution unit and further configured to cool one or more components of the plurality of information handling system servers by transferring heat from the one or more components to the coolant fluid, and a plurality of three-way valves fluidically coupled to the heat exchanger and the fluidic network and configured to convey the fluid in response to control signals received by the plurality of three-way valves. The method may include determining whether a fault has occurred in connection with the distribution unit, operating a plurality of three-way valves in a normal mode of operation in absence of the fault, wherein in the normal mode, the coolant fluid flows in parallel through the heat exchanger and the fluidic network, and operating the plurality of three-way valves in a failure mode in response to the fault, wherein in the failure mode, the coolant fluid flows in serial through the heat exchanger then the fluidic network.

In accordance with embodiments of the present disclosure, an article of manufacture may include a non-transitory computer readable medium and computer-executable instructions carried on the computer readable medium, the instructions readable by a processor, the instructions, when read and executed, for causing the processor to, in a server enclosure having a plurality of information handling system servers, a heat exchanger configured to receive a coolant fluid from a distribution unit external to the server enclosure and return the coolant fluid to the distribution unit and further configured to cool air expelled from the server enclosure to an exterior of the server enclosure by transferring heat from the air to the coolant fluid, a fluidic network configured to receive the coolant fluid from the distribution unit and return the coolant fluid to the distribution unit and further configured to cool one or more components of the plurality of information handling system servers by transferring heat from the one or more components to the coolant fluid, and a plurality of three-way valves fluidically coupled to the heat exchanger an the fluidic network and configured to convey the fluid in response to control signals received by the plurality of three-way valves: determine whether a fault has occurred in connection with the distribution unit; operate a plurality of three-way valves in a normal mode of operation in absence of the fault, wherein in the normal mode, the coolant fluid flows in parallel through the heat exchanger and the fluidic network; and operate the plurality of three-way valves in a failure mode in response to the fault, wherein in the failure mode, the coolant fluid flows in serial through the heat exchanger then the fluidic network.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2A illustrates a block diagram of a cooling system, configured in a normal mode, for a server rack comprising information handling systems, in accordance with embodiments of the present disclosure;

FIG. 2B illustrates a block diagram of a cooling system, configured in a failure mode, for a server rack comprising information handling systems, in accordance with embodiments of the present disclosure;

FIG. 3A illustrates a block diagram of another cooling system, configured in a normal mode, for a server rack comprising information handling systems, in accordance with embodiments of the present disclosure;

FIG. 3B illustrates a block diagram of another cooling system, configured in a failure mode, for a server rack comprising information handling systems, in accordance with embodiments of the present disclosure; and

FIG. 4 illustrates a flow chart of an example method for preventing data loss in a liquid cooled server rack, in accordance with embodiments of the present disclosure.

### DETAILED DESCRIPTION

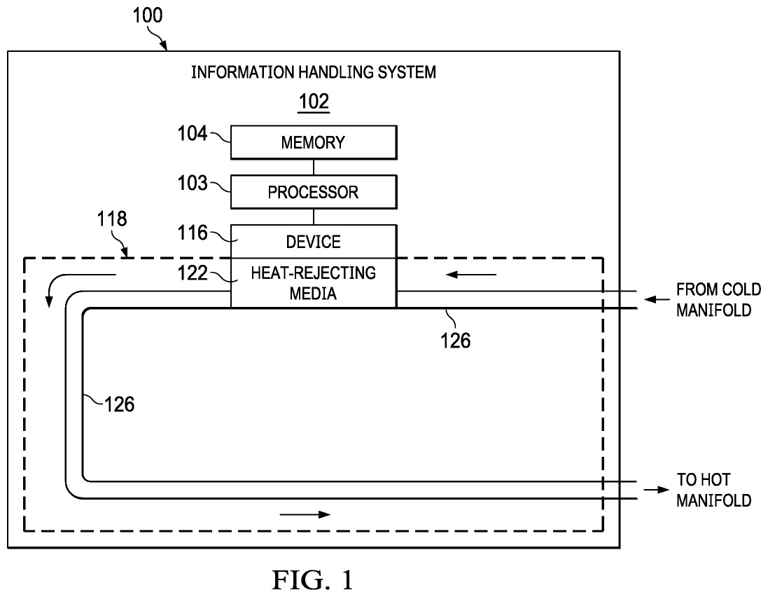

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server or “blade” configured to be housed along with a plurality of other servers or “blades” within a rack, tower, or other enclosure. In other embodiments, information handling system 102 may comprise a personal computer (e.g., a desktop computer, laptop computer, mobile computer, and/or notebook computer). In yet other embodiments, information handling system 102 may be a storage appliance integral to a storage enclosure configured to house a plurality of physical disk drives and/or other computer-readable media for storing data. As shown in FIG. 1, information handling system 102 may include a processor 103, a memory 104, a device 116, and a liquid thermal control system 118.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

As shown in FIG. 1, liquid thermal control system 118 may include heat-rejecting media 122 and fluidic conduits 126.

Heat-rejecting media 122 may include any system, device, or apparatus configured to transfer heat from an information handling resource (e.g., device 116, as shown in FIG. 1), thus reducing a temperature of the information handling resource. For example, heat-rejecting media 122 may include a solid thermally coupled to the information handling resource (e.g., heatpipe, heat spreader, heatsink, finstack, etc.) such that heat generated by the information handling resource is transferred from the information handling resource.

In operation, a cooled fluid may be received via a fluidic conduit from a cold manifold or other source of cooled fluid. As the fluid passes by heat-rejecting media 122 in a fluidic conduit 126 proximate to device 116, heat may be transferred from device 116 to heat-rejecting media 122 and from heat-rejecting media 122 to the fluid liquid in fluidic conduit 126, thus cooling device 116. Such heated fluid may then be discharged from a fluidic conduit to a hot manifold, from where such fluid may return to a cooling system that cools such fluid before the fluid again returns to information handling system 102.

In addition to processor 103, memory 104, device 116, and liquid thermal control system 118, information handling system 102 may include one or more other information handling resources. In addition, for the sake of clarity and exposition of the present disclosure, FIG. 1 depicts only one device 116. In embodiments of the present disclosure, information handling system 102 may include any number of devices 116. Furthermore, for the sake of clarity and exposition of the present disclosure, FIG. 1 depicts device 116 including a liquid thermal control system 118 for cooling of device 116. However, in some embodiments, approaches similar or identical to those used to cool device 116 as described herein may be employed to provide cooling of processor 103, memory 104, and/or any other information handling resource of information handling system 102.

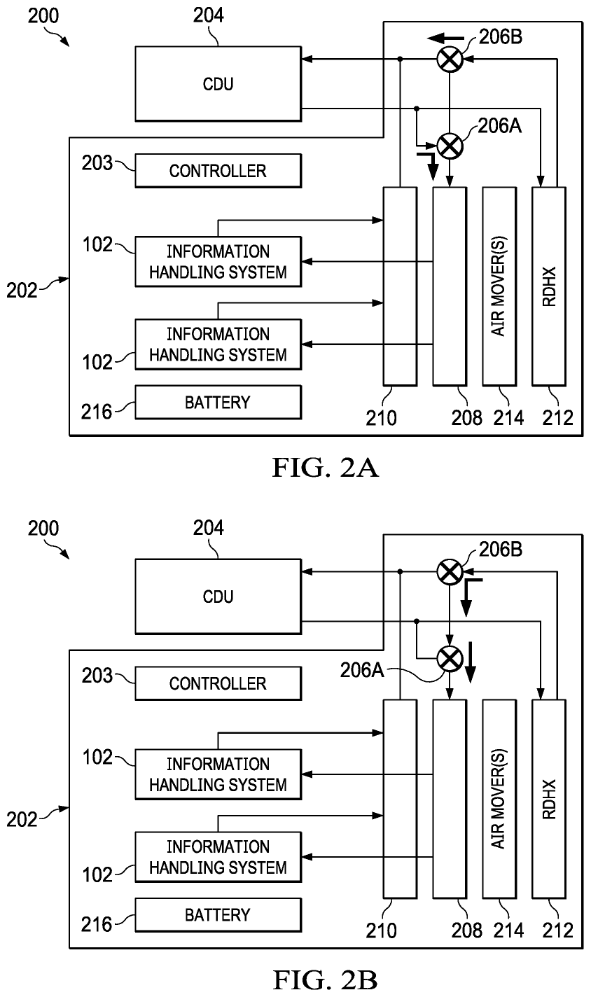

FIG. 2A illustrates a block diagram of a cooling system 200, configured in a normal mode, for a server rack 202 comprising information handling systems 102, in accordance with embodiments of the present disclosure. As shown in FIG. 2A, cooling system 200 may include server rack 202 and a central distribution unit (CDU) 204 fluidically coupled to server rack 202 via a plurality of fluidic conduits.

CDU 204 may comprise any system, device, or apparatus configured to deliver cooled fluid to server rack 202 to cool components of server rack 202, receive heated fluid in return from server rack 202, and cool such fluid in order to redeliver such cooled fluid to server rack 202. Accordingly, CDU 204 may include any suitable collection of one or more radiators, one or more pumps, one or more valves, and/or one or more fluidic conduits for performing its functionality. In some embodiments, CDU 204 may include one or more sensors for measuring a parameter associated with the fluid, including without limitation a temperature sensor and a flow rate sensor.

As shown in FIG. 2A, server rack 202 may include a plurality of information handling systems 102, a controller 203 for controlling three-way valves 206 (e.g., three-way valves 206A and 206B), a cold manifold 208, a hot manifold 210, a rear door heat exchanger (RDHx) 212, one or more air movers 214, and a battery 216. Although FIG. 2A depicts cooling system 200 having a single server rack 202, it is understood that cooling system 200 may include multiple server racks 202 that are cooled by fluid driven from CDU 204.

Although FIG. 2A depicts server rack 202 as including only two information handling systems 102 for purposes of clarity and exposition, it is understood that server rack 202 may include any suitable number of information handling systems 102.

Controller 203 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In particular, controller 203 may be configured to, as described in greater detail below, receive one or more control signals regarding a mode of operation for cooling system 200, and based on such one or more control signals, control flow of fluid through server rack 202 by controlling three-way valves 206. In some embodiments, controller 203 may be integral to CDU 204.

A three-way valve 206 may include any device, system or apparatus that regulates, directs, and/or controls the flow of a fluid (e.g., a coolant liquid in fluidic conduits 126) by opening, closing, or partially obstructing one or more passageways. When a three-way valve 206 opens a passageway, fluid may flow in a direction from higher pressure to lower pressure. As described above, the operation of three-way valve 206 (e.g., opening and closing, size of an aperture of three-way valve 206) may be controlled by controller 203.

Cold manifold 208 may comprise any system, device, or apparatus configured to receive cooled fluid from CDU 204 (e.g., via a valve 206) and distribute such cooled fluid to information handling systems 102 in order to cool components of such information handling systems 102.

Similarly, hot manifold 210 may comprise any system, device, or apparatus configured to receive heated fluid from information handling systems 102 and convey such heated fluid to CDU 204 for cooling and recirculation.

RDHx 212 may comprise any system, device, or apparatus configured to receive air driven by air mover(s) 214 and cool heated air within the enclosure of server rack 202 in order to minimize a temperature of air within data center housing server rack 202.

An air mover 214 may include any mechanical or electro-mechanical system, apparatus, or device operable to move air and/or other gases in order to cool information handling resources of server rack 202 and information handling systems 102. In some embodiments, an air mover 214 may comprise a fan (e.g., a rotating arrangement of vanes or blades which act on the air). In other embodiments, an air mover 214 may comprise a blower (e.g., a centrifugal fan that employs rotating impellers to accelerate air received at its intake and change the direction of the airflow). In these and other embodiments, rotating and other moving components of an air mover 214 may be driven by a motor. In operation, air mover 214 may cool information handling resources of server rack 202 and information handling system 102 by drawing cool air into an enclosure housing the information handling resources from outside the enclosure, expel warm air from inside the enclosure, through RDHx 212, and to the outside of such enclosure, and/or move air across one or more heat sinks (not explicitly shown) internal to the enclosure to cool one or more information handling resources.

Although FIG. 2A depicts air movers 214 as located proximate to RDHx 212, in some embodiments, air movers 214 may not be located proximate to RDHx 212, but instead air may be driven through RDHx 212 via air movers within server rack 202, or air movers located elsewhere for the purpose of driving air through server rack 202 and RDHx 212.

Battery 216 may comprise any system, device, or apparatus comprising one or more electrochemical cells that convert stored chemical energy into electrical energy for delivery to information handling resources of information handling system 102, as well as recharge in response to electric current delivered to battery 216, which may reverse the chemical reactions that occur during conversion of the stored chemical energy into electrical energy. In operation, battery 216 may be used to power components of server rack 202 in the event of an alternating current power loss to server rack 202, thus allowing air mover(s) 214, CDU 204, and electronic components of server rack 202 to continue to operate in the failure mode of operation described below.

In the normal mode of operation, valve 206A may be configured such that fluid driven from CDU 204 flows through cold manifold 208, information handling systems 102 (thus cooling components of information handling systems 102), and hot manifold 210, before returning to CDU 204 for recirculation. Also in the normal mode of operation, valve 206B may be configured such that fluid driven from CDU 204 flows (in parallel to the flow through cold manifold 208, information handling systems 102, and hot manifold 210) to RDHx 212 and returns to CDU 204 from RDHx 212, thus cooling air expelled from rack server 202.

FIG. 2B illustrates a block diagram of cooling system 200, configured in a failure mode, in accordance with embodiments of the present disclosure. As described in greater detail below, such failure mode may occur in response to a temperature of coolant fluid, as sensed by CDU 204, rising above a threshold temperature, thus indicating a failure in the fluid cooling capabilities of CDU 204. Additionally or alternatively, such failure mode may occur in response to a flow rate of coolant fluid, as sensed by CDU 204, rising below a threshold flow rate, thus indicating a failure in the fluid pumping capabilities of CDU 204. A failure in the fluid pumping capabilities of CDU 204 may include any failure that affects an ability to convey fluid, including a leak or other failure in the facility fluid network used to cool information handling systems 102.

In the failure mode, controller 203 may control valves 206 such that insufficiently cooled fluid serially flows from CDU 204 to RDHx 212, where such fluid may be cooled as a result of air flow driven through RDHx 212 by air mover(s) 214, after which such fluid may flow through valve 206B and valve 206A to cold manifold 208. The fluid may continue to flow from cold manifold 208 to information handling systems 102, to cool components of information handling systems 102, and then through hot manifold 210, returning to CDU 204 for recirculation. Thus, in the failure mode, RDHx 212 may serve to provide some cooling of fluid in response to failure of CDU 204 to provide sufficient cooling.

As described in greater detail below, in addition to the rerouting of fluid flow as described above, responsive to failure of the fluid cooling capabilities of CDU 204, controller 203 may initiate a “vaulting” operation to offload data stored in volatile portions of memory 104 to non-volatile portions of memory 104 in a reduced-power mode of information handling systems 102 (thus preventing data loss due to the cooling failure), while the rerouting of fluid may provide a sufficient level of cooling to complete such vaulting operation.

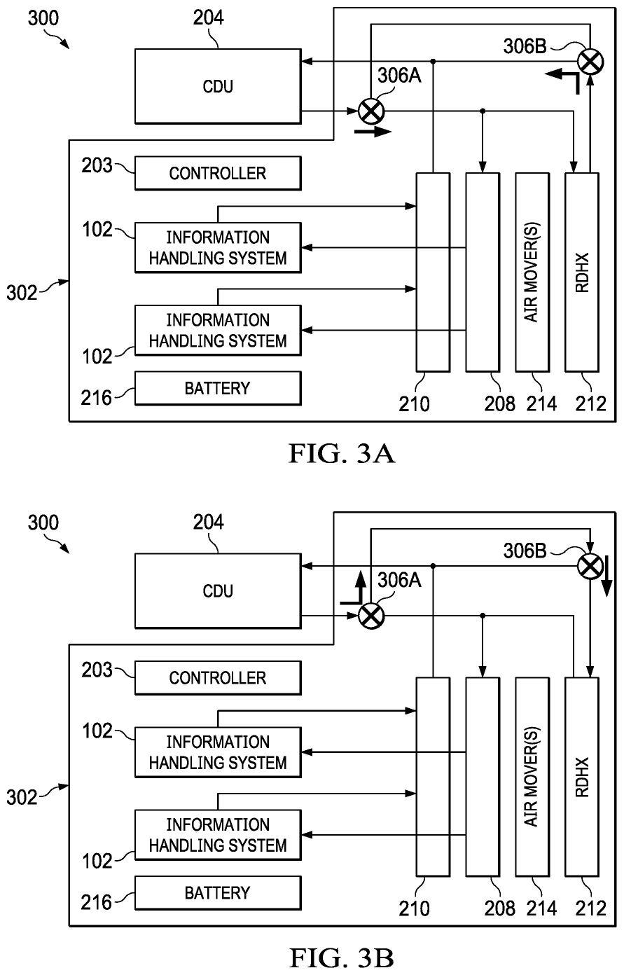

FIG. 3A illustrates a block diagram of a cooling system 300, configured in a normal mode, for a server rack 302 comprising information handling systems 102, in accordance with embodiments of the present disclosure. Cooling system 300 may be similar in many respects to cooling system 200, with server rack 302 in lieu of server rack 202. Server rack 302 may be similar in many respects to server rack 202, with three-way valves 306A and 306B in lieu of three-way valves 206A and 206B, respectively.

In the normal mode of operation, valve 306A may be configured such that fluid driven from CDU 204 flows through cold manifold 208, information handling systems 102 (thus cooling components of information handling systems 102), and hot manifold 210, before returning to CDU 204 for recirculation. Also in the normal mode of operation, valves 306A and 306B may be configured such that fluid driven from CDU 204 flows (in parallel to the flow through cold manifold 208, information handling systems 102, and hot manifold 210) to RDHx 212 and returns to CDU 204 from RDHx 212, thus cooling air expelled from rack server 202.

FIG. 3B illustrates a block diagram of cooling system 300, configured in a failure mode. As described in greater detail below, such failure mode may occur in response to a temperature of coolant fluid, as sensed by CDU 204, rising above a threshold temperature, thus indicating a failure in the fluid cooling capabilities of CDU 204. Additionally or alternatively, such failure mode may occur in response to a flow rate of coolant fluid, as sensed by CDU 204, rising below a threshold flow rate, thus indicating a failure in the fluid pumping capabilities of CDU 204.

In the failure mode, controller 203 may control valves 306 such that fluid flows through RDHx 212 in an opposite direction of that of the normal mode. Thus, insufficiently cooled fluid may serially flow from CDU 204 to RDHx 212 (e.g., through valves 306A and 306B), where such fluid may be cooled as a result of air flow driven through RDHx 212 by air mover(s) 214, after which such fluid may flow to cold manifold 208. The fluid may continue to flow from cold manifold 208 to information handling systems 102, to cool components of information handling systems 102, and then through hot manifold 210, returning to CDU 204 for recirculation. Thus, in the failure mode, RDHx 212 may serve to provide some cooling of fluid in response to failure of CDU 204 to provide sufficient cooling.

As described in greater detail below, in addition to the rerouting of fluid flow as described above, responsive to failure of the fluid cooling capabilities of CDU 204, controller 203 may initiate a “vaulting” operation to offload data stored in volatile portions of memory 104 to non-volatile portions of memory 104 in a reduced-power mode of information handling systems 102 (thus preventing data loss due to the cooling failure), while the rerouting of fluid may provide a sufficient level of cooling to complete such vaulting operation.

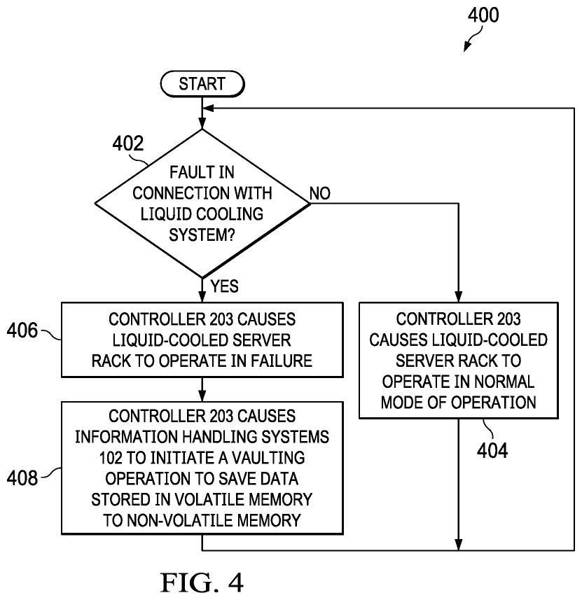

FIG. 4 illustrates a flow chart of an example method 400 for preventing data loss in a liquid-cooled server rack (e.g., server rack 200 or server rack 300), in accordance with embodiments of the present disclosure. According to certain embodiments, method 400 may begin at step 402. As noted above, teachings of the present disclosure may be implemented in a variety of configurations of cooling systems 200 and 300 as shown in FIGS. 2 and 3. As such, the preferred initialization point for method 400 and the order of the steps comprising method 400 may depend on the implementation chosen.

At step 402, controller 203 may determine (e.g., via telemetry from CDU 204) whether a fault has occurred in connection with the liquid cooling system. Such fault may be indicated by one or more of a temperature of coolant fluid rising above a threshold temperature or a flow rate of the coolant fluid falling below a threshold flow rate. If a fault has occurred method 400 may proceed to step 406. Otherwise, method 400 may proceed to step 404.

At step 404, in the absence of a fault condition, controller 203 may cause a liquid-cooled server rack to operate in a normal mode of operation, in which coolant fluid flows in parallel through RDHx 212 and a fluidic network comprising cold manifold 208, information handling systems 102, and hot manifold 210 as described above. After completion of step 404, method 400 may return again to step 402.

At step 406, in response to a fault condition, controller 203 may cause a liquid-cooled server rack to operate in a failure mode, in which coolant fluid flows serially from CDU 204, through RDHx 212 where such coolant fluid is cooled due to air driven by air movers 214, and then such coolant flows through cold manifold 208 to information handling systems 102, thus cooling components of information handling systems 102, before returning to CDU 204 via hot manifold 210.

At step 408, controller 203 may cause information handling systems 102 to initiate a vaulting operation to save data stored in volatile memory to non-volatile memory, thus to prevent potential data loss (e.g., due to overheating of memory modules) caused by a failure of the cooling system. Such vaulting operation may continue until all data in volatile memory has been transferred to non-volatile memory.

After completion of step 408, method 400 may proceed again to step 402.

Although FIG. 4 discloses a particular number of steps to be taken with respect to method 400, it may be executed with greater or lesser steps than those depicted in FIG. 4. In addition, although FIG. 4 discloses a certain order of steps to be taken with respect to method 400, the steps comprising method 400 may be completed in any suitable order.

Method 400 may be implemented using cooling system 200, cooling system 300, components thereof, or any other suitable system operable to implement method 400. In certain embodiments, method 400 may be implemented partially or fully in software and/or firmware embodied in computer-readable media.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A server enclosure comprising:
a plurality of information handling system servers;
a heat exchanger configured to receive a coolant fluid from a distribution unit external to the server enclosure and return the coolant fluid to the distribution unit and further configured to cool air expelled from the server enclosure to an exterior of the server enclosure by transferring heat from the air to the coolant fluid;
a fluidic network configured to receive the coolant fluid from the distribution unit and return the coolant fluid to the distribution unit and further configured to cool one or more components of the plurality of information handling system servers by transferring heat from the one or more components to the coolant fluid;
a plurality of three-way valves fluidically coupled to the heat exchanger and the fluidic network and configured to convey the fluid in response to control signals received by the plurality of three-way valves; and
a controller configured to:
determine whether a fault has occurred in connection with the distribution unit;
operate the plurality of three-way valves in a normal mode of operation in absence of the fault, wherein in the normal mode, the coolant fluid flows in parallel through the heat exchanger and the fluidic network; and
operate the plurality of three-way valves in a failure mode in response to the fault, wherein in the failure mode, the coolant fluid flows in serial through the heat exchanger, then the fluidic network.

2. The server enclosure of claim 1, wherein the fault occurs in response to a temperature of the coolant fluid exceeding a threshold temperature.

3. The server enclosure of claim 1, wherein the fault occurs in response to a flow rate of the coolant fluid falling below a threshold flow rate.

4. The server enclosure of claim 1, wherein in the failure mode, the fluid flows through the heat exchanger in a direction opposite to that of the normal mode.

5. The server enclosure of claim 1, wherein in the failure mode, the fluid flows through the heat exchanger in the same direction as that of the normal mode.

6. The server enclosure of claim 1, wherein the controller is further configured to, in the failure mode, cause the plurality of information handling system servers to save data stored in volatile memory to non-volatile memory.

7. The server enclosure of claim 6, further comprising a battery configured to provide electrical energy to the plurality of information handling system servers to carry out saving data stored in volatile memory to non-volatile memory and to air movers driving air flow across the heat exchanger.

8. A method comprising, in a server enclosure having a plurality of information handling system servers, a heat exchanger configured to receive a coolant fluid from a distribution unit external to the server enclosure and return the coolant fluid to the distribution unit and further configured to cool air expelled from the server enclosure to an exterior of the server enclosure by transferring heat from the air to the coolant fluid, a fluidic network configured to receive the coolant fluid from the distribution unit and return the coolant fluid to the distribution unit and further configured to cool one or more components of the plurality of information handling system servers by transferring heat from the one or more components to the coolant fluid, and a plurality of three-way valves fluidically coupled to the heat exchanger and the fluidic network and configured to convey the fluid in response to control signals received by the plurality of three-way valves:
determining whether a fault has occurred in connection with the distribution unit;
operating a plurality of three-way valves in a normal mode of operation in absence of the fault, wherein in the normal mode, the coolant fluid flows in parallel through the heat exchanger and the fluidic network; and
operating the plurality of three-way valves in a failure mode in response to the fault, wherein in the failure mode, the coolant fluid flows in serial through the heat exchanger then the fluidic network.

9. The method of claim 8, wherein the fault occurs in response to a temperature of the coolant fluid exceeding a threshold temperature.

10. The method of claim 8, wherein the fault occurs in response to a flow rate of the coolant fluid falling below a threshold flow rate.

11. The method of claim 8, wherein in the failure mode, the fluid flows through the heat exchanger in a direction opposite to that of the normal mode.

12. The method of claim 8, wherein in the failure mode, the fluid flows through the heat exchanger in the same direction as that of the normal mode.

13. The method of claim 8, further comprising, in the failure mode, causing the plurality of information handling system servers to save data stored in volatile memory to non-volatile memory.

14. An article of manufacture comprising:
a non-transitory computer readable medium; and
computer-executable instructions carried on the computer readable medium, the instructions readable by a processor, the instructions, when read and executed, for causing the processor to, in a server enclosure having a plurality of information handling system servers, a heat exchanger configured to receive a coolant fluid from a distribution unit external to the server enclosure and return the coolant fluid to the distribution unit and further configured to cool air expelled from the server enclosure to an exterior of the server enclosure by transferring heat from the air to the coolant fluid, a fluidic network configured to receive the coolant fluid from the distribution unit and return the coolant fluid to the distribution unit and further configured to cool one or more components of the plurality of information handling system servers by transferring heat from the one or more components to the coolant fluid, and a plurality of three-way valves fluidically coupled to the heat exchanger an the fluidic network and configured to convey the fluid in response to control signals received by the plurality of three-way valves:
determine whether a fault has occurred in connection with the distribution unit;
operate a plurality of three-way valves in a normal mode of operation in absence of the fault, wherein in the normal mode, the coolant fluid flows in parallel through the heat exchanger and the fluidic network; and
operate the plurality of three-way valves in a failure mode in response to the fault, wherein in the failure mode, the coolant fluid flows in serial through the heat exchanger then the fluidic network.

15. The article of claim 14, wherein the fault occurs in response to a temperature of the coolant fluid exceeding a threshold temperature.

16. The article of claim 14, wherein the fault occurs in response to a flow rate of the coolant fluid falling below a threshold flow rate.

17. The article of claim 14, wherein in the failure mode, the fluid flows through the heat exchanger in a direction opposite to that of the normal mode.

18. The article of claim 14, wherein in the failure mode, the fluid flows through the heat exchanger in the same direction as that of the normal mode.

19. The article of claim 14, the instructions for further causing the processor to, in the failure mode, cause the plurality of information handling system servers to save data stored in volatile memory to non-volatile memory.
